(19) United States
(12) Patent Application Publication
(10) Pub. No.: US 2024/0068087 A1
(43) Pub. Date: Feb. 29, 2024

(54) MAGNETRON SPUTTERING APPARATUS

(71) Applicant: BEIJING NAURA MICROELECTRONICS EQUIPMENT CO., LTD., Beijing (CN)

(72) Inventors: Shubo WU, Beijing (CN); Yinggong MA, Beijing (CN); Shuaitao SHI, Beijing (CN); Wenxue XU, Beijing (CN); Bingliang GUO, Beijing (CN); Ziyang ZHEN, Beijing (CN); Lu ZHANG, Beijing (CN); Yaxin CUI, Beijing (CN); Hongtao ZHAI, Beijing (CN)

(21) Appl. No.: 18/258,499

(22) PCT Filed: Dec. 21, 2021
(86) PCT No.: PCT/CN2021/139913

§ 371 Date: Jun. 20, 2023

(30) Foreign Application Priority Data
Dec. 22, 2020 (CN) 202011530202.9

(51) Int. Cl. C23C 14/35; C23C 14/50; C23C 14/56

(52) U.S. Cl. CPC C23C 14/35; C23C 14/50; C23C 14/568

(57) ABSTRACT

The present disclosure provides a magnetron sputtering apparatus, including a process chamber, a bias power supply assembly, and an excitation power supply assembly. The process chamber is provided with a base assembly and a bias guide assembly. A target is arranged at a top of the process chamber. The base assembly is arranged at a bottom of the process chamber and is configured to support a wafer carrier, drive the wafer carrier to move, and heat the wafer carrier. The bias guide assembly is arranged at the base assembly and configured to support the wafer carrier. The bias guide assembly is electrically in contact with the wafer carrier. The bias power supply assembly is electrically connected to the bias guide assembly and configured to apply a bias voltage to the wafer carrier through the bias guide assembly.

### TECHNICAL FIELD

The present disclosure generally relates to the semiconductor apparatus technology field and, more particularly, to a magnetron sputtering apparatus.

### BACKGROUND

In a deposition process of a semiconductor aluminum nitride (AlN) film, a pre-cleaning process needs to be performed on a wafer to remove contaminants and impurities before performing the deposition process of the AlN film on the wafer to enhance adhesion between the wafer and the AlN film and improve the deposition process result of the AlN film. Therefore, the chip performance is improved.

The pre-cleaning process is typically performed in a pre-cleaning chamber. The wafer needs to be heated through the pre-cleaning chamber. Argon (Ar) or nitrogen (N2) is introduced into the pre-cleaning chamber. The argon or nitrogen is excited to form a plasma in the pre-cleaning chamber. The plasma bombard the wafer to pre-clean the wafer. The deposition process of the AlN film is usually performed in a deposition chamber. The wafer needs to be heated through the deposition chamber. Argon and nitrogen are introduced into the deposition chamber. The argon and nitrogen are excited to form a plasma in the deposition chamber. An aluminum target is bombarded by argon ions to generate aluminum atoms. AlN is formed by combining the aluminum atoms with nitrogen atoms in the nitrogen and is deposited on the wafer to form the AlN film deposited on the wafer.

The existing pre-cleaning process and the deposition process of the AlN film are performed in two different chambers, which causes high manufacturing cost and maintenance cost. The wafer needs to be transferred between two different chambers. Thus, the entire process takes a long time, and the production capability of the apparatus is low.

### SUMMARY

The present disclosure aims to address at least one technical problem in the existing technology and provides a magnetron sputtering apparatus, which can lower the manufacturing cost and maintenance cost and avoid the transfer of the wafer between two different chambers to shorten the process time and improve the production capability.

A magnetron sputtering apparatus is provided to realize the purpose of the present disclosure, which includes a process chamber, a bias power supply assembly, and an excitation power supply assembly. The process chamber is provided with a base assembly and a bias guide assembly. A target is arranged at a top of the process chamber.

The base assembly is arranged at a bottom of the process chamber and is configured to support a wafer carrier, drive the wafer carrier to move, and heat the wafer carrier.

The bias guide assembly is arranged on the base assembly and configured to support the wafer carrier, and the bias guide assembly electrically contacts the wafer carrier.

The bias power supply assembly is electrically connected to the bias guide assembly and configured to apply a bias voltage to the wafer carrier through the bias guide assembly.

The excitation power supply assembly is electrically connected to the target and configured to apply an excitation voltage to the target.

In some embodiments, the bias input assembly includes an insulation connector, a conductor, and a contact member. The conductor is inserted in the insulation connector, and two ends of the conductor are electrically connected to the bias power supply assembly and the contact member, respectively, and configured to guide the bias voltage provided by the bias power supply assembly to the contact member.

The insulation connector is arranged at the base assembly and configured to insulate the conductor from the base assembly.

The contact member electrically contacts the wafer carrier and is configured to support the wafer carrier and guide the bias voltage to the wafer carrier.

In some embodiments, the contact member is annular and includes at least one opening, and the opening is configured to allow a transfer member for transferring a wafer pass through.

In some embodiments, the insulation connector includes a first insulator and a second insulator. The conductor includes a first conductor and a second conductor. The first insulator is arranged horizontally at the base assembly, and the second insulator is arranged vertically at the first insulator.

The first conductor is inserted in the first insulator and extends from the first insulator to be electrically connected to the bias power supply assembly. The second conductor is inserted in the second insulator and extends from the second insulator to be electrically connected to the first conductor and the contact member.

In some embodiments, the first insulator includes a first insulation member and a second insulation member intersecting with each other, and the second insulator is vertically arranged at the second insulator.

The first conductor includes a first conduction member and a second conduction member that are electrically connected. The first conduction member is inserted in the first insulation member and extends from the first insulation member to be electrically connected to the bias power supply assembly. The second conduction member is inserted in the second insulation member and electrically connected to the second conductor.

In some embodiments, the first insulator includes a first insulation connector and a second insulation connector. The first insulation connector and the second insulation connector are detachably connected. The first insulation connector is provided with a first accommodation groove. The second insulation connection member is provided with a second accommodation groove corresponding to the first accommodation groove. The first accommodation groove and the second accommodation groove cooperate to form an accommodation space. The first conductor is arranged in the accommodation space.

In some embodiments, a plurality of second insulators are provided. The plurality of second insulators are arranged at the first insulator at intervals. A number of the second conductors is same as a number of the second insulators. The plurality of second conductors are inserted in a plurality of second insulators in a one-to-one correspondence and are electrically connected to different positions of the contact member.

In some embodiments, the bias power supply assembly includes a bias power supply, a matcher, and a radio frequency (RF) guide member. The bias power supply is configured to provide the bias voltage. The matcher is configured to realize impedance matching. The RF guide member is sealed and arranged at a chamber wall of the process chamber. An end of the RF guide member is electrically connected to the bias guide assembly, and another end of the RF guide member is electrically connected to the bias power supply through the matcher and configured to guide the bias voltage provided by the bias power supply to the bias guide assembly.

In some embodiments, the RF guide member includes an RF guide structure and an RF shield structure. The RF shield structure is sealed and arranged at the chamber wall of the process chamber and is internally arranged with the first insulator. The RF guide structure is inserted in the first insulator and sealed and connected to the RF shield structure. An end of the RF guide structure is arranged in the process chamber and is electrically connected to the bias guide assembly. Another end of the RF guide structure is arranged outside of the process chamber and electrically connected to the bias power supply. A second insulator is sleeved at the end of the RF guide structure located in the process chamber. The RF guide structure is configured to guide the bias voltage provided by the bias power supply to the bias guide assembly. The RF shield structure is configured to shield the bias voltage guided by the RF guide structure.

In some embodiments, the RF guide structure includes a first guide member and a second guide member. The first guide member is sealed and connected to the end of the RF shield structure outside the process chamber. An end of the first guide member is connected to the bias power supply. Another end of the first guide member extends into the first insulator. The second guide member is sealed and connected to the end of the RF shield structure inside the process chamber. An end of the second guide member is connected to the bias guide assembly. Another end of the second guide member extends into the first insulator and is connected to the first guide member. The second insulator is sleeved at the end of the second guide member connected to the bias guide assembly.

Embodiments of the present disclosure have the following beneficial effects.

With the magnetron sputtering apparatus of the present disclosure, in the semiconductor pre-cleaning process, the base assembly can support the wafer carrier and drive the wafer carrier to move to the pre-cleaning process position in the process chamber. The wafer carrier is heated to the pre-cleaning process temperature. With the bias guide assembly, a bias voltage can be applied to the wafer carrier to cause the plasma generated by the pre-cleaning industry gas introduced in the process chamber to bombard the wafer carried by the wafer carrier. Thus, the semiconductor pre-cleaning process can be performed on the wafer. In the semiconductor film deposition process, the base assembly can be configured to support the wafer carrier and drive the wafer carrier such as the wafer to move to the film deposition position in the process chamber. The base assembly can be configured to heat the wafer carrier to the film deposition process temperature. With the excitation power supply assembly, the excitation voltage can be applied to the target to cause the film deposition process gas introduced into the process chamber to form the plasma to bombard the target to generate atoms of the target, which can be combined with the process gas of the film deposition process gas to form a to-be-recorded. Thus, the semiconductor film deposition process can be performed on the wafer. Thus, with the magnetic sputtering apparatus of the present disclosure, the process chamber, the bias power supply assembly, the excitation power supply, the base assembly, the bias guide assembly, and the target can be integrated together. In the same process chamber, the semiconductor pre-cleaning process and the semiconductor film deposition process can be performed to reduce the manufacturing cost and the maintenance cost. The wafer can be prevented from being transferred between different process chambers to shorten the process time and improve the production capacity.

### BRIEF DESCRIPTION OF THE DRAWINGS

FIG. 1 illustrates a schematic structural diagram of a magnetron sputtering apparatus according to an embodiment of the present disclosure.

FIG. 2 illustrates a schematic perspective structural diagram showing a bias guide assembly of a magnetron sputtering apparatus according to an embodiment of the present disclosure.

FIG. 3 illustrates a schematic structural diagram showing a side view of a bias guide assembly of a magnetron sputtering apparatus according to an embodiment of the present disclosure.

FIG. 4 illustrates a schematic structural diagram showing a bias power supply assembly of a magnetron sputtering apparatus according to an embodiment of the present disclosure.

Reference numerals:

| | | | |
|---|---|---|---|
| 1 Process chamber | 11 Gas inlet | 12 Exhaust opening | 2 Bias guide assembly |
| 21 Contact member | 22 First insulator | 221 First insulation member | |
| 222 Second insulation member | 223 First insulation connector | | |
| 224 Second insulation connector | 23 Second insulator | | |
| 24 Conductive part | 241 First conductor | 242 Second conductor | |
| 2421 Protrusion | 3 Bias power supply assembly | 31 Bias power supply | |
| 32 Radio frequency (RF) guide part | 321 RF guide structure | | |
| 3211 First guide member | 3212 Second guide member | | |
| 322 RF shield structure | 3221 Second insulation part | | |
| 3222 First insulation part | 33 Matcher | | |
| 4 Target | 5 Excitation power supply assembly | | |
| 6 Base assembly | 61 Heating light | 62 Power supply member | |
| 63 Base body | 7 Wafer carrier | 81 First reflector | |
| 82 Second reflector | 91 Insulation ring | 92 Adapter | |
| 93 First shield member | 94 Second shield member | | |
| 95 Shield ring | 96 Temperature measuring member | | |

### DETAILED DESCRIPTION OF THE EMBODIMENTS

To cause those skilled in the art to better understand the technical solution of the present disclosure, a magnetron sputtering apparatus of embodiments of the present disclosure is described in detail in connection with the accompanying drawings.

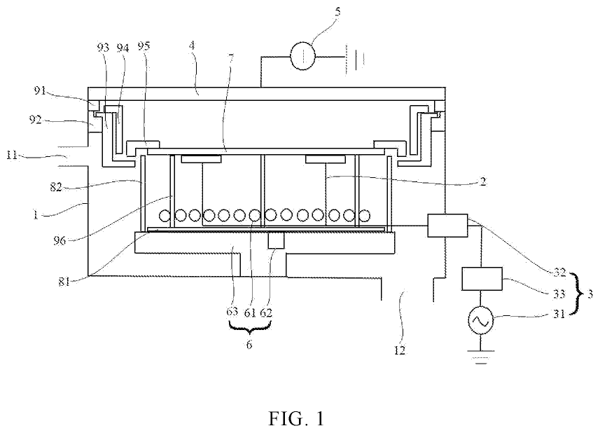

FIG. 1 illustrates a schematic structural diagram of a magnetron sputtering apparatus according to an embodiment of the present disclosure. The magnetron sputtering apparatus includes a process chamber 1, a bias power supply assembly 3, and an excitation power supply assembly 5. The process chamber 1 includes a base assembly 6 and a bias guide assembly 2. A target 4 is arranged at a top of the process chamber 1. The base assembly 6 is arranged at a bottom of the process chamber 1 and configured to support a wafer carrier 7, drive the wafer carrier 7 to move, and heat the wafer carrier 7. The bias guide assembly 2 is arranged at the base assembly 6 and configured to support the wafer carrier 7. The bias guide assembly 2 electrically contacts the wafer carrier 7. The bias power supply assembly 3 electrically contacts the bias guide assembly 2 and is configured to apply a bias voltage to the wafer carrier 7 through the bias guide assembly 2. The excitation power supply assembly 5 is electrically connected to the target 4 and configured to apply an excitation voltage to the target 4.

In the magnetron sputtering apparatus of embodiments of the present disclosure, in the semiconductor pre-cleaning process, the base assembly can be configured to support the wafer carrier 7, drive the wafer carrier 7 to move to a pre-cleaning position in the process chamber, and heat the wafer carrier 7 to a pre-cleaning process temperature. The bias guide assembly 2 can be configured to apply a bias voltage on the wafer carrier 7 to cause a pre-cleaning process gas in the process chamber 1 to form a plasma to bombard the wafer carried by the wafer carrier 7. Thus, the semiconductor pre-cleaning process can be performed on the wafer. In the deposition process of the semiconductor film, the base assembly 6 can be configured to support the wafer carrier 7, drive the wafer carrier 7 to move to a film deposition process position in the process chamber 1, and heat the wafer carrier 7 to a film deposition process temperature. The excitation power supply assembly 5 can apply an excitation voltage on the target 4 to cause a film deposition process gas in the process chamber 1 to form a plasma to bombard the target 4. A to-be-deposited substance is formed by combining atoms of the target and the film deposition process gas. Thus, the deposition process of the semiconductor film can be performed on the wafer. In the magnetron sputtering apparatus of embodiments of the present disclosure, by integrating the process chamber 1, the bias power supply assembly 3, the excitation power supply assembly 5, the base assembly 6, the bias guide assembly 2, and the target 4, the pre-cleaning process and the deposition process of the semiconductor film can be performed in the same process chamber 1, which lowers the manufacturing cost and the maintenance cost. The transfer of the wafer between different process chambers can be avoided. Thus, the process time can be shortened, and the throughput can be improved.

As shown in FIG. 1, a description is made by taking the magnetron sputtering apparatus of embodiments of the present disclosure to perform the deposition process of the AlN film as an example. Before the deposition process of the AlN film is performed, the semiconductor pre-cleaning process needs to be performed first. In the semiconductor pre-cleaning process, the pre-cleaning gas is introduced into the process chamber 1. A manipulator (not shown) can be configured to transfer the wafer carrier 7 with a wafer (e.g., a chip) into the process chamber 1 and place the wafer carrier 7 and the wafer on the bias guide assembly 2 and the base assembly 6. The base assembly 6 and the bias guide assembly 2 can support the wafer carrier 7 together. The bias guide assembly is arranged on the base assembly 6. The base assembly 6 can drive the bias guide assembly 2 and the wafer carrier 7 to move to move the wafer carrier 7 to the pre-cleaning process position. The base assembly 6 can be configured to heat the wafer carrier 7 to the pre-cleaning process temperature to cause the temperature of the wafer carried by the wafer carrier 7 to reach a temperature required by the pre-cleaning process. The bias voltage of the bias power supply assembly 3 can be applied to the wafer carrier 7 through the bias guide assembly 2 electrically connected to the bias power supply assembly 3 and electrically contacting the wafer carrier 7. Thus, the pre-cleaning process gas introduced into the process chamber can be excited to form the plasma. The wafer can be bombarded with the plasma formed by the pre-cleaning process gas to realize the semiconductor pre-cleaning process.

After the semiconductor pre-cleaning process, the AlN film deposition process can be performed. In the AlN film deposition process, argon and nitrogen can be introduced into the process chamber 1 as the deposition process gas. The target 4 can include an aluminum target. The wafer carrier 7 carrying the wafer can remain on the base assembly 6 and the bias guide assembly 2. The base assembly 6 can be configured to support the bias guide assembly 2 and the wafer carrier 7 and drive the wafer carrier 7 to move to the film deposition process position. The base assembly 6 can be configured to heat the wafer carrier continuously until the wafer carrier reaches the temperature required by the film deposition process. The excitation power supply assembly 5 can be configured to apply an excitation voltage on the aluminum target to cause the argon and nitrogen introduced into the process chamber 1 to form the plasma. The aluminum target at the top of the process chamber 1 can be bombarded by argon ions to form aluminum atoms. The aluminum atoms can fall down in the process chamber. During this process, the aluminum atoms can be combined with the argon atoms to form AlN to be deposited on the wafer to realize the AlN film deposition process.

In the magnetron sputtering apparatus of embodiments of the present disclosure, since the base assembly can heat the wafer carrier 7 continuously after heating the wafer carrier 7 the pre-cleaning process temperature to cause the temperature of the wafer carrier 7 to reach the film deposition process temperature, the heating power output by the base assembly can change gradually. Thus, the base assembly 6 may not need to often switch between low power and high power. Therefore, the service time of the base assembly 6 can be extended, and the manufacturing cost and the maintenance cost can be reduced.

In the semiconductor pre-cleaning process of the AlN film deposition process, the pre-cleaning process gas can include argon or nitrogen, and the wafer carrier 7 can include a tray.

In some embodiments, as shown in FIG. 1, a gas inlet 11 and a gas outlet 12 are arranged at the process chamber 1. The gas inlet 11 is arranged on a side of the process chamber 1 and configured to allow the gas to enter the process chamber 1. The gas outlet 12 is arranged at the bottom of the process chamber 1 and configured to allow the gas to be discharged from the process chamber 1. The pre-cleaning process gas and the film deposition process gas can enter the process chamber through the gas inlet 11. The pre-cleaning process gas the film deposition process gas entering the process chamber 1 can be discharged from the process chamber through the gas outlet 12.

In some embodiments, as shown in FIG. 1, the excitation power supply assembly includes a DC power supply. The DC power supply is configured to apply a DC voltage to the target.

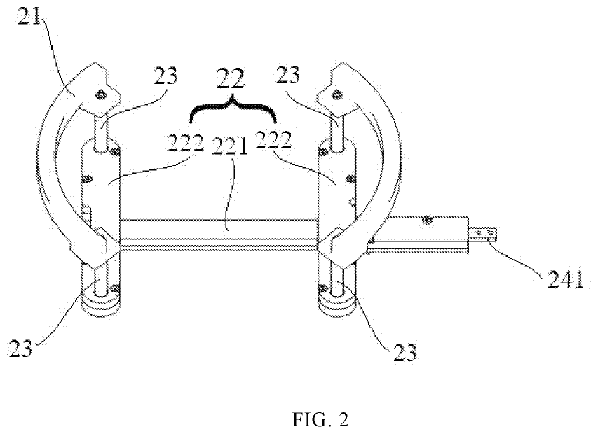

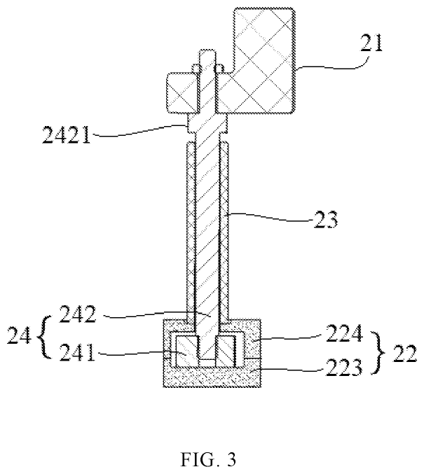

In some embodiments, as shown in FIG. 2 and FIG. 3, the bias guide assembly 2 includes an insulation connector, a conductive part 24, and a contact member 21. The conductive part 24 is inserted into the insulation connector. Two ends of the conductive part 24 are electrically connected to the bias power supply assembly 3 and the contact member 21, respectively, and configured to direct the bias voltage provided by the bias power supply assembly 3 to the contact member 21. The insulation connector is arranged at the base assembly 6 and configured to electrically insulate the conductive part 24 from the base assembly 6. The contact member 21 is in electrical contact with the wafer carrier 7 and configured to support the wafer carrier 7 and direct the bias voltage to the wafer carrier 7.

When the wafer carrier 7 is arranged on the bias guide assembly 2, the contact member 21 can be in contact with and electrically connected to the wafer carrier 7. The conductive part 24 is inserted into the insulation connector. The two ends of the conductive part 24 are electrically connected to the bias power supply assembly 3 and the contact member 21, respectively, and configured to direct the bias voltage provided by the bias power supply assembly 3 to the contact member 21. That is, the bias voltage provided by the bias power supply assembly 3 can be first applied to the conductive part 24, then transferred to the contact member 21 through the conductive part 24, and then transferred to the wafer carrier 7 through the contact member 21. The insulation connector is arranged on the base assembly 6 and configured to electrically insulate the conductive part 24 from the base assembly 6 to prevent the bias voltage conducted by the conductive part 24 from being conducted to the process chamber 1 through the base assembly. Thus, the bias voltage conducted by the conductive part 24 can be smoothly conducted to the contact member 21.

In some embodiments, as shown in FIG. 2, the contact member 21 is ring-shaped and includes at least one opening. The opening can be configured to allow a transfer part for transferring the wafer to pass through. That is, the contact member 21 includes a plurality of arc-shaped sub-contact members arranged along a circumference at intervals to form a ring-shaped contact member as a whole. An interval between two neighboring sub-contact members is the above opening. For example, FIG. 2 shows that the contact member 21 includes two sub-contact members. The two sub-contact members are arranged symmetrically relative to an axis of the base assembly 6. Two intervals between the two sub-contact members can be the above openings, which are configured to allow the transfer member for transferring the wafer to pass through.

In the semiconductor film deposition process and the semiconductor pre-cleaning process, the wafer carrier 7 carrying with the wafer can be transferred into the process chamber 1 by the transfer member such as the manipulator. An opening is arranged at the contact member 21 and configured to allow the transfer member such as the manipulator to pass through. Thus, the transfer member can move to a position below the wafer carrier 7. Thus, the interference between the contact member 21 and the transfer member such as the manipulator can be avoided. Thus, the transfer member such as the manipulator cannot place the wafer and the wafer carrier 7 on the contact member 21 that is ring-shaped. Therefore, the transfer member such as the manipulator can smoothly place the wafer and the wafer carrier 7 on the contact member 21.

In some embodiments, as shown in FIG. 2 and FIG. 3, the above insulation connector includes a first insulator 22 and a second insulator 23. The conductive part 24 includes a first conductor 241 and a second conductor 242. The first insulator 22 is horizontally arranged on the base assembly 6. The second insulator 23 is vertically arranged on the first insulator 22. The first conductor 241 can be inserted into the first insulator 22 and extends from the first insulator 22 to be electrically connected to the bias power supply assembly 3. The second conductor 242 is inserted into the second insulator 23 and extends from the second insulator 23 to be electrically connected to the first conductor 241 and the contact member 21.

The first conductor 241 can be electrically connected to the bias power supply assembly 3, and the second conductor 242 is electrically connected to the first conductor 241 and the contact member 21. The bias voltage provided by the bias power supply assembly 3 can be first applied to the first conductor 241, then transferred to the second conductor 242 through the first conductor 241, and then transferred to the contact member 21 transmitted through the second conductive body 242 to the contact member 21.

The first insulator 22 and the second insulator 23 can insulate the first conductor 241 and the second conductor 242 from the base assembly 6 to prevent the bias voltage conducted by the first conductor 241 and the second conductor 242 from being conducted to the process chamber 1 through the base assembly 6. The first insulator 22 and the second insulator 23 can also be configured to support and fix the first conductor 241, the second conductor 241, and the contact member 21. Thus, these members can be stably fixed at the base assembly 6.

In some embodiments, as shown in FIG. 3, two ends of the second conductor 242 include external threads. One end of the two ends of the second conductor 242 includes a protrusion 2421. The first conductor 241 includes a hole with an internal thread. The contact member 21 includes a through-hole. By screwing the second conductor 242 through the external thread of one end of the second conductor 242 into the hole with the inner thread of the first conductor 241. Thus, the second conductor 242 is threadedly connected to the first conductor 241. Meanwhile, the second conductor 242 is electrically connected to the first conductor 241. By passing the other end of the second conductor 242 through the through-hole of the contact member 21, causing the protrusion 2421 to abut against the lower surface of the contact member 21, and then threadedly matching a nut with the external thread of the other end of the second conductor 242, the second conductor 242 can be threadedly connected to the contact member 21. Meanwhile, the second conductor 242 can be electrically connected to the contact member 21. The protrusion 2421 can be configured to support the contact member 21.

In some embodiments, as shown in FIG. 2, the first insulator 22 includes a first insulation member 221 and a second insulation member 222 that intersect with each other. The second insulator 23 is vertically arranged on the second insulation member 222. The first conductor 241 includes a first conductive member and a second conductive member (not shown) that intersect with each other and are electrically connected. The first conductive member is inserted in the first insulation member 221 along an extension direction of the first insulation member 221. The first conductive member extends out from the first insulation member 221 to be electrically connected to the bias power supply assembly 3. The second conduction member can be inserted in the second insulation member 222 along an extension direction of the second insulation member 222 and can be electrically connected to the second conductor 242. It can be easily understood that the shapes of the first insulation member 221 and the second insulation member 222 that intersect with each other match shapes of the first conductive member and the second conductive member that intersect with each other and are inserted in the first insulation member 221 and the second insulation member 222. As such, the support stability of the bias guide assembly 2 can be further improved.

In some embodiments, as shown in FIG. 2, the first insulation member 221 and the second insulation member 222 vertically intersect with each other. That is, the first insulation member 221 and the second insulation member 222 are perpendicular to each other. Correspondingly, the first conductive member and the second conductive member can vertically intersect with each other. However, an angle between the first insulation member 221 and the second insulation member 222 and an angle between the first conductive member and the second conductive member are not limited to this.

In some embodiments, as shown in FIG. 2, one first insulation member 221 is provided and two second insulation members 222 are provided. The two second insulation members 222 are parallel and spaced apart, and intersect with the first insulation member 221. Correspondingly, one first conductive member is provided, and two second conductive members are provided. The two second conductive members are inserted into the two second insulation members 222 along the extension directions of the second insulation members 222, respectively. The first conductive member is inserted in the first insulation member 221 along the extension direction of the first insulation member 221. Thus, the support stability of the bias guide assembly 2 can be further improved. However, the number of the second insulation members 222 are not limited and can be one, three, or more. The number of the second conductive members is equal to the number of the second insulation members 222. The second conductive members can be arranged in a one-to-one correspondence with the second insulation members 222.

In some embodiments, as shown in FIG. 3, the first insulator 22 includes a first insulation connector 223 and a second insulation connector 224. The first insulation connector 223 and the second insulation connector 224 can be detachably connected. The first insulation connector 223 includes a first accommodation groove. The second insulation connector 224 includes a second accommodation groove corresponding to the first accommodation groove. The first accommodation groove matches with the second accommodation groove to form an accommodation space. The first conductor 241 is arranged in the accommodation space.

As shown in FIG. 2 and FIG. 3, the first insulation connector 223 is divided into two parts, and the second insulation connector 224 is divided into two parts. A first part of the first insulation connector 223 is detachably connected to a first part of the second insulation connector 224 to form the first insulation member 221. A second part of the first insulation connector 223 is detachably connected to a second part of the second insulation connector 224 to form the second insulation member 222. An internal space of the first part of the first insulation connector 223 and an internal space of the first part of the second insulation connector 224 form a first part of the accommodation space. The second part of the first insulation connector 223 and an internal space of the second part of the second insulation connector 224 form a second part of the accommodation space. The first part and the second part of the accommodation space can communicate through through-holes arranged correspondingly at the first insulation connector 223 and the second insulation connector 224. When installing the first insulation body 22, the first conductor 241 is arranged in the first accommodation groove of the first insulation connector 223 (including the first part and the second part). Then, the second insulation connector 224 (including the first part and the second part) can enclose the first insulation connector 223. Thus, the second accommodation groove of the second insulation connector 224 and the first accommodation groove of the first insulation connector 223 can correspondingly cooperate to form the accommodation space. The first conductor 241 is arranged in the accommodation space.

In some embodiments, a manner of detachably connecting the first insulation connector 223 and the second insulation connector 224 can include that the first insulation connector 223 is snapped with the second insulation connector 224, then the threaded connector such as the screw is threadedly connected to the base assembly 6 by passing the threaded connector such as the screw through the through-holes of the second insulation connector 224 and the first insulation connector 223. Thus, the first insulation connector 223 and the second insulation connector 224 can be fixed at the base assembly 6.

After mounting the first insulator 22 on the base assembly 6, the second conductor 242 can be inserted into the second insulation member 222 and electrically connected to the first conductor 241. Then, the second insulator 23 is sleeved around the second conductor 242, and finally, the second conductor 242 can be electrically connected to the contact member 21, thereby completing the installation of the biasing input assembly 2.

In some embodiments shown in FIG. 2, the insulation connector includes a plurality of second insulators 23. The plurality of second insulators 23 are arranged at intervals at the first insulator 22. Correspondingly, the conduction part 24 includes a plurality of second conductor 242, and the plurality of second conductor 242 can be arranged in a one-to-one correspondence in the plurality of second insulator 23. Each of the plurality of second conductors 242 is electrically connected to the contact member 21. By arranging the plurality of second insulators 23, the contact member 21 can be supported at different positions, thereby improving the support stability of the bias guide assembly 2.

In some embodiments shown in FIG. 2, the insulation connector includes four second insulators 23. Two second insulators 23 are arranged on one of the second insulation members 222 at an interval. The other two second insulators 23 are arranged on the other second insulation members at an interval. In some embodiments, ends of the two second insulators 23 of the same second insulation member 222 are connected to positions close to two ends of the second insulation member 2, respectively. Thus, the second insulation member 222 can uniformly stressed. Correspondingly, the conductor 24 includes four second conductors 242, which are arranged in the one-to-one correspondence in the four second insulators 23. The two second conductors 242 can be electrically connected to one sub-contact member of the contact member 21. The other two second conductors 242 can be electrically connected to another sub-contact member. In some embodiments, the two second conductors 242 electrically connected to the same sub-contact member can be connected to the positions close to the two ends of the sub-contact member. Thus, the sub-contact member can be stably supported. However, the numbers of the insulation connectors and the second conductors 24 are not limited and can be two, three, or more.

In some embodiments as shown in FIG. 1, the bias power supply assembly 3 includes a bias power supply 31, a matcher 33, and a radio frequency (RF) guide part 32. The bias power supply 31 is configured to provide a bias voltage. The matcher 33 is configured to realize impedance matching. The RF guide part 32 is sealed and arranged on a chamber wall of the process chamber 1. One end of the RF guide part 32 is electrically connected to the bias guide assembly 2. The other end of the RF guide part 32 is electrically connected to the bias power supply 31 through the matcher 33 and configured to guide the bias voltage provided by the bias power supply 31 to the bias guide assembly 2.

As shown in FIG. 1, the bias power supply 31 and the matcher 33 are arranged outside the process chamber 1, the bias guide assembly 2 is arranged in the process chamber 1, and the RF guide part 32 is sealed and arranged on the chamber wall of the process chamber 1 to ensure the required sealing environment of the process chamber 1. One end of the RF guide part 32 is electrically connected to the bias guide assembly 2, and the other end is electrically connected to the bias power supply 31 through the matcher 33 to guide the bias voltage provided by the bias power supply 31 to the bias guide assembly 2 arranged in the process chamber 1. That is, the bias voltage provided by the bias power supply 31 can be first applied to the RF guide part 32 through the matcher 33, and then guided to the bias guide assembly 2 through the RF guide part 32.

The impedance matching can be performed by the matcher 33 to reduce the reflection power as much as possible. Thus, sufficient bias voltage can be guided into the bias guide assembly 2 to avoid wasting the bias voltage. Thereby, improving the utilization efficiency of the bias voltage to reduce process time and increase production capacity.

In some embodiments, as shown in FIG. 1, the bias power supply 31 includes an RF power supply. The RF power supply can be configured to apply the RF voltage to the bias guide assembly 2.

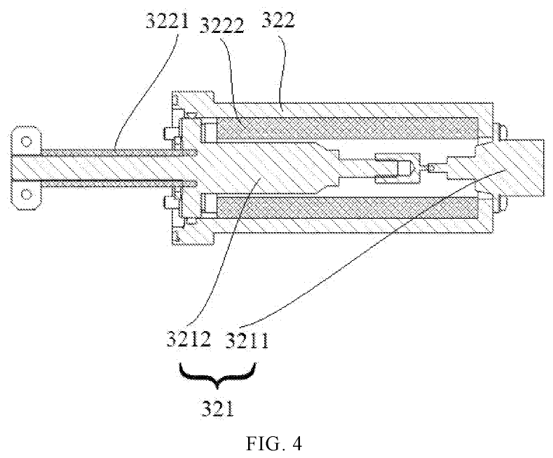

In some embodiments, as shown in FIG. 4, the RF guide part 32 includes an RF guide structure 321 and an RF shield structure 322. The RF shield structure 322 is sealably arranged on the chamber wall of the process chamber 1 and includes a first insulation component 3222. The RF guide structure 321 is inserted through the first insulation part 3222 inside the RF shield structure 322. The RF guide structure 321 is inserted in the first insulation part 3222 and sealed and connected to the RF shield structure 322. An end of the RF guide structure 321 is arranged in the process chamber 1 and electrically connected to the bias guide assembly 2. The other end of the RF guide structure 321 is arranged outside the process chamber 1 and electrically connected to the bias power supply 31. A second insulation part 3221 is sleeved at the end of the RF guide structure 321 in the process chamber 1. The RF guide structure 321 can be configured to guide the bias voltage provided by the bias power supply 31 to the bias guide assembly 2. The RF shield structure 322 can be configured to shield the bias voltage guided by the RF guide structure 321.

The RF shield structure 322 is sealably arranged on the chamber wall of the process chamber 1. The RF guide structure 321 is inserted in the first insulation part 3222 and sealed and connected to the RF shield structure 322 to ensure the required sealed environment of the process chamber 1. One end of the RF guide structure 321 is arranged in the process chamber 1 and electrically connected to the bias guide assembly 2. The other end of the RF guide structure 321 is arranged outside the process chamber 1 and electrically connected to the bias power supply 31. The bias voltage provided by the bias power supply 31 is first applied to the RF guide structure 321 through the matcher 33 and then guided to the bias guide assembly 2 through the RF guide structure 321 to guide the bias voltage provided by the bias power supply 31 that is located outside the process chamber 1 to the bias guide assembly 2 that is located inside the process chamber 1. The RF guide structure 321 is inserted in the first insulation part 3222 inside the RF shield structure 322. The end of the RF guide structure 321 located inside the process chamber 1 is sleeved with the second insulation part 3221 to electrically insulate the RF guide structure 321 from the chamber wall of the process chamber 1. Thus, the bias voltage guided by the RF guide structure 321 can be prevented from being conducted to the chamber wall of the process chamber 1 and unable to be conducted to the bias guide assembly 2, thereby allowing the RF guide structure 321 to smoothly guide the bias voltage to the bias guide assembly 2. The RF shield structure 322 can be configured to shield the bias voltage guided by the RF guide structure 321 to prevent the bias voltage guided by the RF guide structure 321 from expanding into the process chamber 1 to interfere other devices in the process chamber 1. Thus, the bias voltage guided by the RF guide structure 321 can be prevented from interfering with the semiconductor pre-cleaning process and the semiconductor film deposition process.

In some embodiments, as shown in FIG. 4, the RF guide structure 321 includes a first guide member 3211 and a second guide member 3212. The first guide member 3211 is sealed and connected to the end of the RF shield structure 322 located outside the process chamber 1. One end of the first guide member 3211 is connected to the bias power supply 31, and the other end of the first guide member 3211 extends into the first insulation part 3222. The second guide member 3212 is sealed and connected to the end of the RF shield structure 322 located inside the process chamber 1. One end of the second guide member 3212 is connected to the bias guide assembly 2. The other end of the second guide member 3212 extends into the first insulation part 3222 and is connected to the first guide member 3211. The second insulation part 3221 is sleeved at the end of the second guide member 3212 connected to the bias guide assembly 2.

The bias voltage provided by the bias power supply 31 can be first applied to the first guide member 3211 through the matcher 33, then guided to the second guide member 3212 through the first guide member 3211, and further guided to the bias guide assembly 2. The first guide member 3211 is sealed and connected to the end of the RF shield structure 322 located outside the process chamber 1, and the second guide member 3212 is sealed and connected to the end of the RF shield structure 322 located inside the process chamber 1 to cause the first guide member 3211 and the second guide member 3212 to be sealed with the RF shield structure 322, thereby ensuring a sealed environment required by the process chamber 1. The other end of the first guide member 3211 extends into the first insulation part 3222. The other end of the second guide member 3212 extends into the first insulation part 3222. The second insulation part 3221 is sleeved at the end of the second guide member 3212 that is connected to the bias guide assembly 2. Thus, the first guide member 3211 and the second guide member 3212 can be electrically insulated from the chamber wall of the process chamber 1 by the first insulation part 3222 and the second insulation part 3221. Therefore, the bias voltage guided by the first guide member 3211 and the second guide member 3212 can be prevented from being conducted to the chamber wall of the process chamber 1.

In some embodiments, the first guide member 3211 can include a threaded hole, and the second guide member 3212 can include an external thread corresponding to the threaded hole of the first guide member 3211. The first guide member 3211 can be electrically connected to the second guide member 3212 by threadedly matching the external thread of the second guide member 3212 with the threaded hole of the first guide member 3211.

When the RF guide part 32 is mounted, a portion of the second guide member 3212 sleeved with the second insulation part 3221 can be inserted into the process chamber 1. Thus, a portion of the second guide member 3212 can be arranged in the process chamber 1. Another portion of the second guide member 3212 can be located outside the process chamber 1. Then, the second guide member 3212 can be connected to the first conductor 241. Then, the first insulation part 3222 can be sleeved around the portion of the second guide member 3212 located outside the process chamber 1. Then, the RF shield structure 322 can be sleeved around the first insulation part 3222. Finally, the first guide member 3211 can be inserted into the RF shield structure 322, connected to the second guide member 3212, and connected to the RF shield structure 322, thereby completing the installation of the RF guide part 32.

In some embodiments, the first guide member 3211 includes a through-hole. The RF shield structure 322 includes a threaded hole corresponding to the through-hole of the first guide member 3211. A threaded connector such as a screw can pass through the through-hole of the first guide member 3211 and threadedly cooperate with the threaded hole of the RF shield structure 322 to cause the first guide member 3211 to be connected to the RF shield structure 322.

In some embodiments, as shown in FIG. 1, the base assembly 6 includes a base body 63, a heating lamp 61, and a power supply member 62. The base body 63 is arranged at the bottom of the process chamber 1. The heating lamp 61 is arranged above the base body 63. The power supply member 62 is electrically connected to the heating lamp 61 to supply power to the heating lamp 61. The heating lamp 61 is arranged below the wafer carrier 7 that is arranged on the bias guide assembly 2. The heating lamp 61 is configured to emit infrared light to radiate the wafer carrier 7 to heat the wafer carrier 7.

In some embodiments, as shown in FIG. 1, the process chamber further includes a cooling member (not shown in the figure). The cooling member can be arranged in the base body 63.

By using the cooling component, the heat generated by the base assembly 6 can be prevented from radiating to the bottom of the process chamber 1. Thus, the interference of the device at the bottom of the process chamber 1 caused by the heat generated by the base assembly 6 can be avoided.

In some embodiments, as shown in FIG. 1, the process chamber further includes a first reflector 81 and a second reflector 82. The first reflector 81 is arranged at the base body 63 and below the heating lamp 61. The second reflector 82 is arranged at the base body 63 and surrounds the heating lamp 61. The first reflector 81 and the second reflector 82 can be configured to reflect the infrared light generated by the heating lamp 61 toward the wafer carrier 7. By reflecting the light generated by the heating lamp 61 towards the wafer carrier 7 using the first reflector 81 and the second reflector 82, the heating efficiency of the base assembly 6 on the wafer can be improved, thereby reducing the process time and increasing the production capacity.

In some embodiments, as shown in FIG. 1, the process chamber further includes a temperature measuring member 96. The temperature measuring member 96 is arranged at the base body 63 and in contact with the wafer carrier 7. The temperature measuring member 96 can be configured to measure the temperature of the wafer carrier 7 in the semiconductor pre-cleaning process and semiconductor film deposition process.

In some embodiments, as shown in FIG. 1, the process chamber further includes an insulation ring 91. The insulation ring 91 is sealed and arranged between the target 4 and the process chamber 1 and configured to seal the target and the process chamber 1 and electrically insulated the target 4 from the process chamber 1.

In some embodiments, as shown in FIG. 1, the process chamber further includes an adapter 92, a first shield member 93, a second shield member 94, and a shield ring 95. The adapter 92 can be arranged between the insulation ring 91 and the process chamber 1. The first shield member 93 is arranged at the adapter 92. The second shield member 94 is arranged at the first shield member 93. The first shield member 93 and the second shield member 94 can be configured to shield the inner wall of the process chamber 1 to prevent the inner wall of the process chamber 1 from being bombarded by the plasma in the semiconductor pre-cleaning process and semiconductor film deposition process, thereby improving the stability and service life of the process chamber 1. With the adapter 92, when maintenance or replacement needs to be performed on the first shield member 93 and the second shield member 94, only the adapter 92 may need to be removed from the process chamber 1 to disassemble the first shield member 93 and the second shield member 94. When using the first shield member 93 and second shield member 94 with different specifications and sizes, only a corresponding new adapter 92 may need to be used for the replacement to stably arrange the new first shield member 93 and second shield member 94 inside the process chamber 1, thereby facilitating maintenance or replacement of the first shield member 93 and the second shield member 94.

The shield ring 95 overlaps with the first shield member 93. In the semiconductor pre-cleaning process, the base assembly 6 can drive the bias guide assembly 2 to support the wafer carrier 7 below the shield ring 95. That is, in the semiconductor pre-cleaning process, the shield ring 95 overlaps with the first shield member 93. In the semiconductor film deposition process, the base assembly 6 can drive the bias guide assembly 2 to support the wafer carrier 7 to lift the shield ring 95 overlapping the first shield member 93. That is, in the semiconductor film deposition process, the shield ring 95 overlaps the wafer carrier 7 at an annular edge without carrying the wafer to prevent the annular edge of the wafer carrier 7 without carrying the wafer from being bombarded by the plasma in the semiconductor film deposition process to improve the service life of the wafer carrier 7.

In summary, in the magnetron sputtering apparatus of embodiments of the present disclosure, by integrating the process chamber, the bias power supply assembly, the excitation power supply assembly, the base assembly, the bias guide assembly, and the target together, the semiconductor pre-cleaning process and the semiconductor film deposition process can be performed in the same process chamber. Thus, the manufacturing cost and the maintenance cost can be lowered, and the wafer can be prevented from being transferred between different process chambers, thereby shortening the process time and improving the production capacity.

It should be understood that the above embodiments are merely illustrative examples adopted to explain the principles of the present disclosure. However, the present disclosure is not limited to this. Those skilled in the art can make various variations and improvements without departing from the spirit and essence of the present disclosure. These variations and improvements are within the scope of the present disclosure.

1-10. (canceled)

11. A magnetron sputtering apparatus comprising:
a process chamber including:
a base assembly arranged at a bottom of the process chamber and configured to support a wafer carrier, drive the wafer carrier to move, and heat the wafer carrier; and
a bias guide assembly arranged on the base assembly and configured to support the wafer carrier and electrically contacting the wafer carrier;
a target being arranged at a top of the process chamber;
a bias power supply assembly electrically connected to the bias guide assembly and configured to apply a bias voltage to the wafer carrier through the bias guide assembly, and
an excitation power supply assembly electrically connected to the target and configured to apply an excitation voltage to the target.

12. The magnetron sputtering apparatus according to claim 11, wherein the bias input assembly includes:
an insulation connector;
a contact member electrically contacting the wafer carrier and configured to support the wafer carrier and guide the bias voltage to the wafer carrier; and
a conduction part inserted in the insulation connector to be insulated from the base assembly and configured to guide the bias voltage provided by the bias power supply assembly to the contact member, two ends of the conduction part being electrically connected to the bias power supply assembly and the contact member, respectively.

13. The magnetron sputtering apparatus according to claim 12, wherein the contact member is annular and includes:
at least one opening configured to allow a transfer member for transferring a wafer to pass through.

14. The magnetron sputtering apparatus according to claim 12, wherein:
the insulation connector includes:
a first insulator arranged horizontally at the base assembly; and
a second insulator arranged vertically at the first insulator; and
the conduction part includes:
a first conductor inserted in the first insulator and extending from the first insulator to be electrically connected to the bias power supply assembly; and
a second conductor inserted in the second insulator and extending from the second insulator to be electrically connected to the first conductor and the contact member.

15. The magnetron sputtering apparatus according to claim 14, wherein:
the first insulator includes:
a first insulation member; and
a second insulation member intersecting and being staggered with the first insulation member, the second insulator being vertically arranged at the second insulation member; and
the first conductor includes:
a first conduction member inserted in the first insulation member and extending from the first insulation member to be electrically connected to the bias power supply assembly and
a second conduction member electrically connected to the first conduction member and inserted in the second insulation member and electrically connected to the second conductor.

16. The magnetron sputtering apparatus according to claim 14, wherein the first insulator includes:
a first insulation connector including a first accommodation groove; and
a second insulation connector detachably connected to the first insulation connector and including a second accommodation groove corresponding to the first accommodation groove, the first accommodation groove and the second accommodation groove cooperating to form an accommodation space, and the first conductor being arranged in the accommodation space.

17. The magnetron sputtering apparatus according to claim 14, further comprising:
a plurality of second insulators arranged at the first insulator at intervals, a number of the second conductors being same as a number of the plurality of second insulators, and the second conductors being inserted in the plurality of second insulators in a one-to-one correspondence and being electrically connected to different positions of the contact member.

18. The magnetron sputtering apparatus according to claim 11, wherein the bias power supply assembly includes:
a bias power supply configured provide the bias voltage;
a matcher configured to realize impedance matching; and
a radio frequency (RF) guide member sealed and arranged at a chamber wall of the process chamber, an end of the RF guide member being electrically connected to the bias guide assembly, and another end of the RF guide member being electrically connected to the bias power supply through the matcher and configured to guide the bias voltage provided by the bias power supply to the bias guide assembly.

19. The magnetron sputtering apparatus according to claim 18, wherein the RF guide member includes:
an RF shield structure sealed and arranged at the chamber wall of the process chamber and including the first insulator; and
an RF guide structure inserted in the first insulator and sealed and connected to the RF shield structure, wherein:
an end of the RF guide structure is arranged in the process chamber and electrically connected to the bias guide assembly;
another end of the RF guide structure is arranged outside of the process chamber and electrically connected to the bias power supply;
a second insulator is sleeved at the end of the RF guide structure located in the process chamber;
the RF guide structure is configured to guide the bias voltage provided by the bias power supply to the bias guide assembly; and
the RF shield structure is configured to shield the bias voltage guided by the RF guide structure.

20. The magnetron sputtering apparatus according to claim 19, wherein the RF guide structure includes:
a first guide member sealed and connected to the end of the RF shield structure outside the process chamber, an end of the first guide member being connected to the bias power supply, and another end of the first guide member extending into the first insulator; and
a second guide member sealed and connected to the end of the RF shield structure inside the process chamber, an end of the second guide member being connected to the bias guide assembly, another end of the second guide member extending into the first insulator and being connected to the first guide member, and the second insulator being sleeved at the end of the second guide member connected to the bias guide assembly.
